(19) United States
(12) Patent Application Publication
(10) Pub. No.: US 2026/0332298 A1
(43) Pub. Date: Oct. 22, 2026

(54) Low-Density Parity-Check Coding With Applications For Probabilistic Amplitude Shaping

(71) Applicant: QUALCOMM Incorporated, San Diego, CA (US)

(72) Inventors: Wei LIU, Beijing (CN); Thomas Joseph RICHARDSON, South Orange, NJ (US); Liangming WU, Beijing (CN); Changlong XU, Beijing (CN); Ori SHENTAL, Marlboro, NJ (US); Hao XU, Beijing (CN)

(21) Appl. No.: 19/105,705

(22) PCT Filed: Aug. 24, 2022
(86) PCT No.: PCT/CN2022/114430

§ 371 Date: Feb. 21, 2025

(51) Int. Cl. H04L 1/00

(52) U.S. Cl. CPC H04L 1/0061; H04L 1/0042

(57) ABSTRACT

A low-density parity-check encoder is provided that encodes a plurality of information bits according to a low-density parity-check matrix based upon a lifted version of BG1 or BG2 in which the first two columns of the low-density parity-check matrix are parity-bit columns. In this fashion, a systematic low-density parity-check encoding is provided despite the use of BG1 or BG2.

### TECHNICAL FIELD

This application relates to wireless communication systems, and more particularly to a wireless communication system with low-density parity-check coding with applications for probabilistic amplitude shaping.

### INTRODUCTION

Although modem communication standards such as the New Radio (NR) 5^{th} generation (5G) standard are utilizing additional frequency bands as compared to older standards, the communication is still bandwidth limited. The resulting bandwidth limitation over which transmissions must occur restricts the theoretically achievable data rates. To approach this theoretical minimum through increased spectral efficiency, 5G systems may use higher-order modulation schemes in which bits are encoded to form a symbol. For example, in an M-ary quadrature amplitude modulation (QAM), M bits are encoded to form a symbol selected from a constellation of 2^{M} possible QAM symbols, where M is a positive integer.

Should each symbol in the constellation have the same probability of being transmitted, a “shaping gap” occurs that reduces the spectral efficiency by up to 1.53 dB. To reduce or eliminate this shaping gap, higher-order modulation schemes may utilize probabilistic shaping in which the distribution is still uniform but the spacing between points in the constellation is adjusted. Since adjusting the spacing of the constellation increases complexity and has other issues, an alternate technique in which the constellation spacing is unaffected is probabilistic amplitude shaping (PAS). In PAS, an outer layer of amplitude shaping maps input bits into amplitudes that have a non-uniform distribution (ideally, a Gaussian distribution). These amplitudes are then binary encoded to form a corresponding stream of information bits that are processed according to an inner layer of binary forward-error-correction (FEC) encoding to provide parity bits for a phasing of the amplitudes to create the symbol constellation. It is advantageous to implement the FEC encoding using a low-density parity-check code (LDPC).

In 5G, there are two base graph matrices for LDPC: base graph 1 (BG1) and base graph 2 (BG2). For each base graph matrix, the information bits corresponding to the first two columns of the matrix are punctured and thus not transmitted. Although this puncturing is advantageous with respect to improving coding performance, the puncturing degrades the reduction of the shaping gap by the probabilistic amplitude shaping.

### SUMMARY

The following summarizes some aspects of the present disclosure to provide a basic understanding of the discussed technology. Its sole purpose is to present some concepts of one or more aspects of the disclosure in summary form as a prelude to the more detailed description that is presented later.

In one aspect of the disclosure, a wireless communication device is provided that includes: an encoder configured to encode a plurality of N*Z information bits into a codeword of (N+4)*Z bits according to a low-density parity-check matrix in which a first 2*Z bits of the codeword are parity bits and a subsequent (N+2)*Z bits of the codeword include the N*Z information bits and 2*Z additional parity bits, wherein N is a plural positive integer and Z is a lifting factor of the low-density parity-check matrix

In yet another aspect of the disclosure, a wireless communication device is provided that includes: a first low-density parity-check decoder configured to decode a first codeword according to first low-density parity-check code into a first output word in which an initial 2Z bits of the first output word are parity bits and in which a subsequent (N+2)*Z bits of the first output word includes N information bits, wherein Z is a lifting factor of the first low-density parity-check code and N is a plural positive integer; and a second low-density parity-check decoder configured to decode the first output word according a second low-density parity-check code into a second output word of the N information bits, wherein Z is also a lifting factor of the second low-density parity-check code.

In yet another aspect of the disclosure, a computerized method of identifying parity bit columns for a low-density parity-check encoding is provided that includes: lifting a core low-density parity-check (LDPC) matrix according to a lifting factor Z to form a lifted LDPC matrix having a plurality of N+4 columns indexed from a first column to an (N+4)th column, wherein the first column and a second column in the lifted LDPC matrix are parity-bit columns and N is a positive plural integer identifying how many information-bit columns are in the lifted LDPC matrix, and wherein the lifting factor Z is selected from a class of lifting factors that are all proportional to a positive plural integer a; and determining a set of encodable patterns for the lifted LDPC matrix, wherein each encodable pattern is a set of four column indices identifying the parity-bit columns in the lifted LDPC matrix, and wherein the set of encodable patterns is the same for lifting factor in the class of lifting factors.

Other aspects, features, and embodiments of the disclosure will become apparent to those of ordinary skill in the art upon reviewing the following description.

### BRIEF DESCRIPTION OF THE DRAWINGS

FIG. 1 illustrates an example network of communication devices configured for systematic LDPC encoding in accordance with aspects of the disclosure.

FIG. 2 illustrates base graph 1 (BG1) in which the first two columns are parity-bit columns in accordance with aspects of the disclosure.

FIG. 3 is a diagram of a transmitter with probabilistic amplitude shaping and systematic LDPC encoding in accordance with aspects of the disclosure.

FIG. 4 is a flowchart of an example method of systematic LDPC encoding in accordance with aspects of the disclosure.

FIG. 5 illustrates a systematic LDPC encoder that includes an NR LDPC encoder in accordance with an aspect of the disclosure.

FIG. 6 illustrates a systematic LDPC decoder that includes an NR LDPC decoder in accordance with an aspect of the disclosure.

FIG. 7 is a flowchart of an example method of identifying the optimal set P from the encodable patterns for a particular Z class in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

A low-density parity-check code needs to be encodable, i.e., the parity bits should be unambiguously determined from the information bits according to a low-density parity-check matrix. There are many ways to implement a low-density parity-check matrix for a low-density parity-check encoding. Although all these various approaches may result in encodability, the coding efficiency is also important. If the choice of the low-density parity-check matrix results in the encoder having to perform many operations to calculate the parity bits, the resulting encoding is disadvantageous compared to another low-density parity-check matrix selection in which the parity bits may be computed using fewer operations. The same desire for efficiency applies to the LDPC decoder. Through much effort and study of the various ways to select the low-density parity-check matrix, the 5G protocol has standardized a quasi-cyclic LDPC in which the protograph is denoted as a base graph (either BG1 or BG2). Based upon a lifting factor Z, each element in the base graph is replaced by a corresponding Z×Z permutation matrix to form the low-density parity-check matrix. Because 5G LDPC is quasi-cyclic, the various (non-zero) Z×Z permutation matrices are related to each other through a circular shift. This is quite advantageous with respect to reducing the memory requirements of the encoder and decoder and reducing the calculation complexity and number of required operations.

It is thus desirable for a communication device such as a user equipment or abase station to continue to use either BG1 or BG2 with respect to encoding and decoding. But as discussed earlier, this use of 5G LDPC came at the cost of puncturing information bits (and thus puncturing the corresponding amplitudes), which increases the shaping gap that would otherwise be reduced by the use of techniques such as probabilistic amplitude shaping. As will be explained further herein, LDPC encoders and decoders are disclosed that advantageously retain the use of the 5G base graph, but with the puncturing of parity bits as opposed to the puncturing of information bits. For the first time, a communication system may thus employ 5G LDPC in a systematic fashion. A code is denoted herein as being systematic when the information bits are not transformed or punctured but instead are retained in the transmitted codeword. The following implementations may be employed in any application in which a systematic encoding of 5G LDPC is desired. Although the following discussion will be directed to the use of a systematic LDPC encoding in the context of probabilistic amplitude shaping, it will thus be appreciated that the LDPC encoding and decoding discussed herein is applicable to any systematic forward error correction (FEC) application.

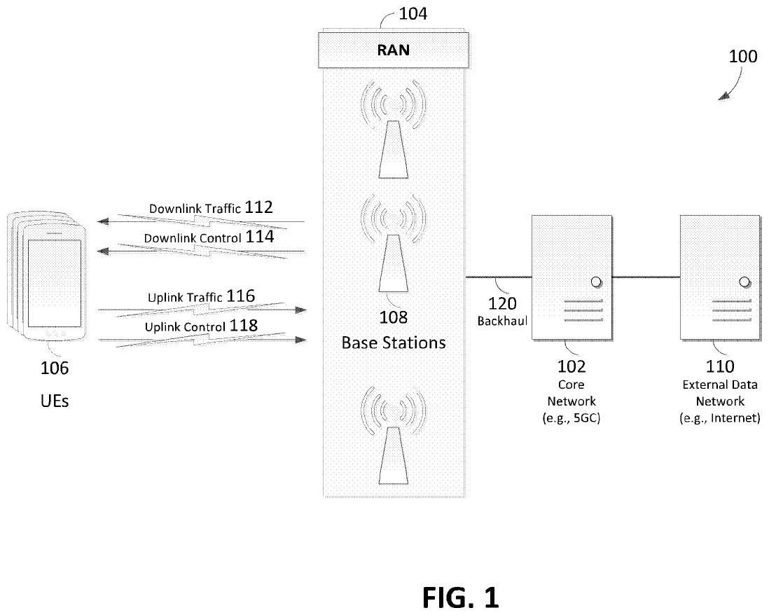

Before the systematic encoding of 5G LDPC is discussed in more detail, an example communication system in which communication devices may implement the systematic encoding of 5G LDPC will first be discussed. Turning now to FIG. 1, various aspects of the present disclosure are illustrated with reference to a wireless communication system 100. The wireless communication system 100 includes three interacting domains: a core network 102, a radio access network (RAN) 104, and an external data network 110. RAN 104 includes a plurality of base stations 108 and a plurality of user equipment (UE) 106. Each UE 106 or base station 108 is an example of a network device configured to perform systematic encoding of 5G LDPC as discussed further herein.

By virtue of the wireless communication system 100, each UE 106 may be enabled to carry out data communication with the external data network 110, such as (but not limited to) the Internet. The RAN 104 may implement any suitable wireless communication technology or technologies to provide radio access to each UE 106. As one example, the RAN 104 may operate according to 3rd Generation Partnership Project (3GPP) New Radio (NR) specifications, often referred to as 5G. As another example, the RAN 104 may operate under a hybrid of 5G NR and Evolved Universal Terrestrial Radio Access Network (eUTRAN) standards, often referred to as LTE. The 3GPP refers to this hybrid RAN as a next-generation RAN, or NG-RAN. Of course, many other examples may be utilized within the scope of the present disclosure.

As illustrated, the RAN 104 includes a plurality of base stations 108. Broadly, a base station is a network device in a radio access network responsible for radio transmission and reception in one or more cells to or from a LYE 106. In different technologies, standards, or contexts, a base station 108 may variously be referred to by those skilled in the art as a base transceiver station (BTS), a radio base station, a radio transceiver, a transceiver function, a basic service set (BSS), an extended service set (ESS), an access point (AP), a Node B (NB), an eNode B (eNB), a gNode B (gNB), or some other suitable terminology.

The radio access network 104 is further illustrated supporting wireless communication for multiple mobile apparatuses. A mobile apparatus may be referred to as user equipment (UE) in 3GPP standards, but may also be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. A UE 106 may be defined as an apparatus that provides a user with access to network services.

UEs 106 may include a number of components configured for wireless communication; such components can include antennas, antenna arrays, RF chains, amplifiers, one or more processors, etc. electrically coupled to each other. For example, some non-limiting examples of a mobile apparatus (mobile network device) include a cellular (cell) phone, a smart phone, a session initiation protocol (SIP) phone, a laptop, a personal computer (PC), a notebook, a netbook, a smartbook, a tablet, a personal digital assistant (PDA), and a broad array of embedded systems, e.g., corresponding to an “Internet of things” (IoT). A network device may additionally be an automotive or other transportation vehicle, a remote sensor or actuator, a robot or robotics device, a satellite radio, a global positioning system (GPS) device, an object tracking device, a drone, a multi-copter, a quad-copter, a remote control device, a consumer and/or wearable device, such as eyewear, a wearable camera, a virtual reality device, a smart watch, a health or fitness tracker, a digital audio player (e.g., MP3 player), a camera, a game console, etc. A network device may additionally be a digital home or smart home device such as a home audio, video, and/or multimedia device, an appliance, a vending machine, intelligent lighting, a home security system, a smart meter, etc.

Wireless communication between RAN 104 and a UE 106 may be described as utilizing an air interface. Transmissions over the air interface from a base station 108 to one or more UEs 106 may be referred to as downlink (DL) transmission. In accordance with certain aspects of the present disclosure, the term downlink may refer to a point-to-multipoint transmission originating at a base station 108. Another way to describe this scheme may be to use the term broadcast channel multiplexing. Transmissions from a UE 106 to a base station 108 may be referred to as uplink (UL) transmissions. In accordance with further aspects of the present disclosure, the term uplink may refer to a point-to-point or a point-to-multi-point transmission originating at a UE 106.

A base station 108 may thus broadcast downlink traffic 112 to one or more UEs 106. Broadly, each base station 108 is a node or device responsible for scheduling traffic in a wireless communication network, including the downlink traffic 112 and, in some examples, uplink traffic 116 and uplink control information 118 from the one or more UEs 106. On the other hand, each UE 106 is a node or device that receives downlink control information 114, including but not limited to scheduling information (e.g., a grant), synchronization or timing information, or other control information from another entity in the wireless communication network such as the base station 108.

Base stations 108 may include a backhaul interface for communication with a backhaul portion 120 of the wireless communication system. The backhaul 120 may provide a link between a base station 108 and the core network 102. Further, in some examples, a backhaul network may provide interconnection between the respective base stations 108. Various types of backhaul interfaces may be employed, such as a direct physical connection, a virtual network, or the like using any suitable transport network.

The core network 102 may be a part of the wireless communication system 100 and may be independent of the radio access technology used in the RAN 104. In some examples, the core network 102 may be configured according to 5G standards (e.g., 5GC). In other examples, the core network 102 may be configured according to a 4G evolved packet core (EPC), or any other suitable standard or configuration.

In various implementations, the air interface in the radio access network 104 may utilize licensed spectrum, unlicensed spectrum, or shared spectrum. Licensed spectrum provides for exclusive use of a portion of the spectrum, generally by virtue of a mobile network operator purchasing a license from a government regulatory body. Unlicensed spectrum provides for shared use of a portion of the spectrum without need for a government-granted license. While compliance with some technical rules is generally still required to access unlicensed spectrum, generally, any operator or device may gain access. Shared spectrum may fall between licensed and unlicensed spectrum, wherein technical rules or limitations may be required to access the spectrum, but the spectrum may still be shared by multiple operators and/or multiple RATs. For example, the holder of a license for a portion of licensed spectrum may provide licensed shared access (LSA) to share that spectrum with other parties, e.g., with suitable licensee-determined conditions to gain access.

The air interface in the radio access network 104 may utilize one or more duplexing algorithms. Duplex refers to a point-to-point communication link where both endpoints can communicate with one another in both directions. Full duplex means both endpoints can simultaneously communicate with one another. Half duplex means only one endpoint can send information to the other at a time. In a wireless link, a full duplex channel generally relies on physical isolation of a transmitter and receiver, and suitable interference cancellation technologies. Full duplex emulation is frequently implemented for wireless links by utilizing frequency division duplex (FDD) or time division duplex (TDD). In FDD, transmissions in different directions operate at different carrier frequencies. In TDD, transmissions in different directions on a given channel are separated from one another using time division multiplexing. That is, at one time the channel is dedicated for transmissions in one direction, while at other times the channel is dedicated for transmissions in the other direction, where the direction may change very rapidly, e.g., several times per slot. With this background information in mind, aspects of the systematic encoding of 5G LDPC disclosed herein will now be discussed in more detail.

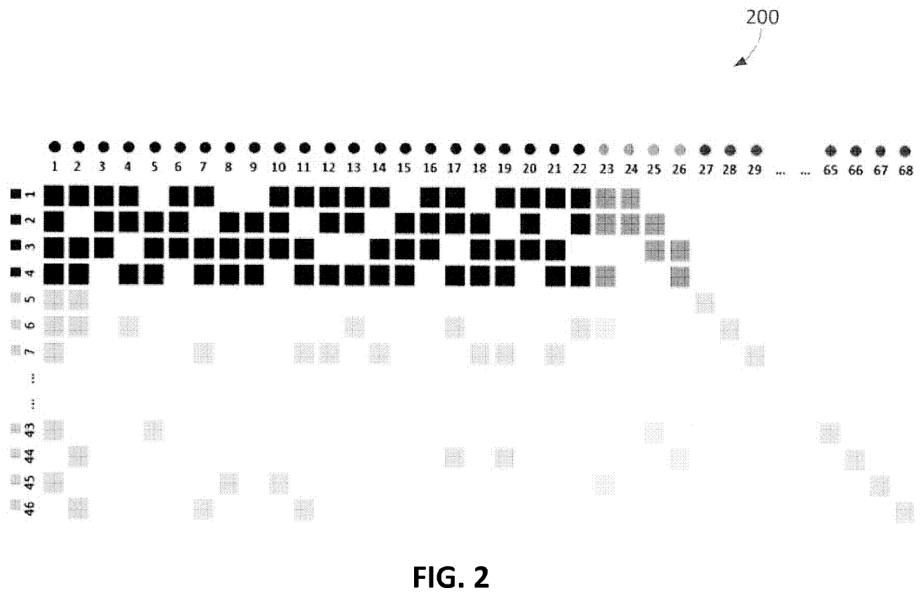

The systematic encoding involves a reassignment of some of the information-bit columns in the 5G LDPC base graphs. For example, BG1 is shown in FIG. 2 as a matrix 200. Depending upon the coding rate, the BG1 matrix 200 can be up to 46 rows by 68 columns. In conventional (information-bit-punctured) encoding using BG1, columns 1 through 22 are information-bit columns. Columns 23 through 68 are parity bit columns. The first four rows and first 26 columns form a core of the BG1 matrix. The parity bits encoded by columns 23-26 are thus core parity bits whereas parity bits encoded by columns 27 through 68 are denoted as extension parity bits. Note that the first four rows of core parity-bit columns 23 through 26 form a “double diagonal” matrix pattern that leads to an efficient calculation of the corresponding core parity bits. With the core parity bits calculated during normal 5G operation, the desired number of extension parity bits are then readily calculated due to the “main diagonal” matrix pattern for the extension parity bit columns.

In the systematic encoding disclosed herein, the structure of the BG1 and BG2 matrices is retained. Although the base graph matrix structure is thus unchanged, the assignment of the columns is changed. In particular, the first two columns are now core parity-bit columns. Since the core of the BG1 or BG2 matrix needs four core parity-bit columns, two of the remaining columns in the core (columns 3 through 26 for BG1 and columns 3 through 14 for BG2) are also core parity-bit columns.

In the BG1 matrix, the indices of the core columns are integers ranging from 1 to 26. Given this indexing, the indices of the core parity-bit columns for the systematic encoding are denoted herein as a set P. The set P includes the column indices 1 and 2 since the first two columns are now parity-bit columns. The set P includes two additional core columns and thus includes two more column indices selected from the set of {3, 4, . . . , 25, 26}. One can thus appreciate that there are numerous possibilities for the set P (indeed, there are 276 possible values for the set P for BG1). But of this relatively large set of possible parity-bit selections, only a subset is encodable such that the four core parity bits may be determined unambiguously.

A similar selection of the set P can be made for the BG2 matrix. But in the BG2 matrix, the core is formed by the first four rows and the first fourteen columns. The set P for BG2 would thus include integers 1 and 2 and two more integers selected from the set of {3, 4, . . . , 13, 14}. Regardless of whether BG1 or BG2 is selected, a value of P that is encodable is denoted herein as an encodable pattern. It can be shown that the number of encodable patterns is a function of the lifting factor Z. In that regard, the lifting factor Z is produced by a function Z(a,k)=a*2^{k}, where a is an integer multiplier that is selected from the set of {2, 3, 5, 7, 9, 11, 13, 15} and k is an integer that is greater than or equal to zero and less than or equal to 7. The lifting factors Z that all have the same integer multiplier a form what is denoted herein as a Z class. It can be shown that the number of encodable patterns for any particular value of the lifting factor Z in a Z class is the same and depends upon whether BG1 or BG2 is selected. The encodable patterns for BG1 will now be discussed in more detail.

For example, it can be shown that the encodable patterns for BG1 with a=2 and with P={1, 2, c, d}, where {c, d} are one of: {c, d} being one of {3, 4}, {3, 5}, {3, 8}, {3,9}, {3, 12}, {3, 13}, {3, 15, {3, 17}, {3, 18}, {3, 22}, {3, 23}, {3, 24}, {3, 25}, {3, 26}, {4, 5}, {4, 6}, {4, 8}, {4,9}, {4, 10}, {4, 15}, {4, 16}, {4, 18}, {4, 20}, {4, 24}, {4, 26}, {5, 6}, {5, 10}, {5, 12}, {5, 13}, {5, 16}, {5, 17}, {5, 20}, {5, 22}, {5, 23}, {5, 25}, 6, 8}, {6, 9}, {6, 12}, {6, 13}, {6, 15}, {6, 17}, {6, 18}, {6, 22}, {6, 23}, {6, 24}, {6, 25}, {6, 26}, {8, 10}, {8, 12}, {8, 13}, {8, 16}, {8, 17}, {8, 20}, {8, 22}, {8, 23}, {8, 25}, {9, 10}, {9, 12}, {9, 13}, {9, 16}, {9, 17}, {9, 20}, {9, 22}, {9, 23}, {9, 25}, {10, 12}, {10, 13}, {10, 15}, {10, 17}, {10, 18}, {10, 22}, {10, 23}, {10, 24}, {10, 25}, {10, 26}, {12, 15}, {12, 16}, {12, 18}, {12, 20}, {12, 24}, {12, 26}, {13, 15}, {13, 16}, {13, 18}, {13, 20}, {13, 24}, {13, 26}, {15, 16}, {15, 17}, {15, 20}, {15, 22}, {15, 23}, {15, 25}, {16, 17}, {16, 18}, {16, 22}, {16, 23}, {16, 24}, {16, 25}, {16, 26}, {17, 18}, {17, 20}, {17, 24}, {17, 26}, {18, 20}, {18, 22}, {18, 23}, {18, 25}, {20, 22}, {20, 23}, {20, 24}, {20, 25}, {20, 26}, {22, 24}, {22, 26}, {23, 24}, {23, 26}, {24, 25}, {25, 26}. In total, there are 119 encodable patterns for any lifting factor Z=a2^{k} with a=2, BG1.

Similarly, it can be shown that the encodable patterns for BG1 with a=3 and with P={1, 2, c, d}, where {c, d} are one of: {3, 5}, {3, 8}, {3, 12}, {3, 13}, {3, 22}, {3, 24}, {3, 25}, {3, 26}, {4, 5}, {4, 6}, {4, 8}, {4, 10}, {4, 16}, {4, 20}, {4, 24}, {4, 26}, {5, 6}, {5, 16}, {5, 17}, {5, 22}, {5, 23}, {5, 25}, {6, 8}, {6, 9}, {6, 12}, {6, 13}, {6, 15}, {6, 17}, {6, 18}, {6, 22}, {6, 23}, {6, 24}, {6, 25}, {6, 26}, {8, 16}, {8, 17}, {8, 22}, {8, 23}, {8, 25}, {9, 10}, {9, 12}, {9, 13}, {9, 16}, {9, 20}, {9, 22}, {9, 25}, {10, 15}, {10, 17}, {10, 18}, {10, 22}, {10, 23}, {10, 24}, {10, 25}, {12, 15}, {12, 16}, {12, 18}, {12, 24}, {13, 15}, {13, 16}, {13, 18}, {13, 24}, {15, 16}, {15, 20}, {15, 22}, {15, 25}, {16, 17}, {16, 18}, {16, 22}, {16, 23}, {16, 24}, {16, 25}, {16, 26}, {17, 20}, {17, 24}, {17, 26}, {18, 20}, {18, 22}, {18, 25}, {20, 22}, {20, 23}, {20, 24}, {20, 25}, {22, 24}, {22, 26}, {23, 24}, {23, 26}, {24, 25}, {25, 26}. In total, there are 88 encodable patterns for any lifting factor Z=a2^{k} with a=3, BG1.

In addition, it can be shown that the encodable patterns for BG1 with a=5 and with P={1, 2, c, d}, where {c, d} are one of: {3, 4}, {3, 5}, {3, 8}, {3, 9}, {3, 12}, {3, 13}, {3, 15}, {3, 17}, {3, 18}, {3, 22}, {3, 23}, {3, 24}, {3, 25}, {3, 26}, {4, 5}, {4, 6}, {4, 8}, {4, 9}, {4, 10}, {4, 15}, {4, 16}, {4, 18}, {4, 20}, {4, 24}, {4, 26}, {5, 10}, {5, 13}, {5, 16}, {5, 20}, {5, 22}, {5, 23}, {5, 25}, {6, 8}, {6, 9}, {6, 13}, {6, 15}, {6, 18}, {6, 22}, {6, 23}, {6, 24}, {6, 25}, {6, 26}, {8, 10}, {8, 12}, {8, 13}, {8, 16}, {8, 17}, {8, 20}, {8, 22}, {8, 23}, {8, 25}, {9, 10}, {9, 12}, {9, 13}, {9, 16}, {9, 17}, {9, 20}, {9, 22}, {9, 23}, {9, 25}, {10, 12}, {10, 13}, {10, 15}, {10, 17}, {10, 18}, {10, 22}, {10, 23}, {10, 24}, {10, 25}, {10, 26}, {12, 15}, {12, 16}, {12, 18}, {12, 20}, {12, 24}, {12, 26}, {13, 15}, {13, 16}, {13, 18}, {13, 20}, {13, 24}, {13, 26}, {15, 16}, {15, 17}, {15, 22}, {15, 23}, {15, 25}, {16, 17}, {16, 18}, {16, 22}, {16, 23}, {16, 25}, {16, 26}, {17, 18}, {17, 20}, {17, 24}, {17, 26}, {18, 20}, {18, 22}, {18, 23}, {18, 25}, {20, 22}, {20, 23}, {20, 24}, {20, 25}, {20, 26}, {22, 24}, {22, 26}, {23, 24}, {23, 26}, {24, 25}, {25, 26}. In total, there are 112 encodable patterns for any lifting factor Z=a2^{k} with a=5, BG1.

Moreover, it can be shown that the encodable patterns for BG1 with a=7 and with P={1, 2, c, d}, where {c, d} are one of: {3, 5}, {3, 8}, {3, 9, {3, 12}, {3, 15}, {3, 17}, {3, 18}, {3, 22}, {3, 23}, {3, 24}, 3, 25}, {4, 5}, {4, 6}, {4, 8}, {4, 9}, {4, 10}, {4, 15}, {4, 16}, {4, 18}, {4, 24}, {4, 26}, {5, 6}, {5, 10}, {5, 13}, {5, 17}, {5, 20}, {5, 22}, {5, 23}, {5, 25}, {6, 9}, {6, 12}, {6, 13}, {6, 17}, {6, 22}, {6, 26}, {8, 12}, {8, 13}, {8, 16}, {8, 17}, {8, 22}, {8, 23}, {8, 25}, {9, 10}, {9, 13}, {9, 16}, {9, 17}, {9, 20}, {9, 22}, {9, 23}, {9, 25}, {10, 12}, {10, 13}, {10, 15}, {10, 22}, {10, 23}, {10, 24}, {10, 25}, {10, 26}, {12, 20}, {12, 24}, {12, 26}, {13, 15}, {13, 16}, {13, 18}, {13, 20}, {13, 24}, {15, 17}, {15, 20}, {15, 22}, {16, 17}, {16, 18}, {16, 22}, {16, 23}, {16, 24}, {16, 25}, {16, 26}, {17, 18}, {17, 20}, {17, 24}, {17, 26}, {18, 20}, {18, 22}, {18, 23}, {18, 25}, {20, 22}, {20, 24}, {20, 25}, {22, 24}, {22, 26}, {23, 26}, {25, 26}. In total, there are 91 encodable patterns for any lifting factor Z=a2^{k} with a=7, BG1.

Similarly, it can be shown that the encodable patterns for BG1 with a=9 and with P={1, 2, c, d}, where {c, d} are one of: {3, 4}, {3, 5}, {3, 8}, {3, 12}, {3, 13}, {3, 15}, {3, 17}, {3, 18}, {3, 22}, {3, 23}, {3, 24}, {3, 25}, {3, 26}, {4, 6}, {4, 8}, {4, 9}, {4, 16}, {4, 18}, {4, 24}, {5, 6}, {5, 12}, {5, 13}, {5, 16}, {5, 17}, {5, 22}, {5, 23}, {5, 25}, {6, 9}, {6, 12}, {6, 13}, {6, 15}, {6, 17}, {6, 24}, {6, 25}, {6, 26}, {8, 10}, {8, 12}, {8, 13}, {8, 16}, {8, 17}, {8, 25}, {9, 10}, {9, 12}, {9, 13}, {9, 22}, {9, 23}, {9, 25}, {10, 12}, {10, 13}, {10, 15}, {10, 17}, {10, 18}, {10, 22}, {10, 23}, {10, 24}, {10, 25}, {12, 15}, {12, 16}, {12, 18}, {12, 24}, {12, 26}, {13, 15}, {13, 16}, {13, 18}, {13, 24}, {15, 22}, {15, 23}, {15, 25}, {16, 18}, {16, 22}, {16, 23}, {16, 25}, {16, 26}, {17, 18}, {17, 26}, {18, 25}, {22, 24}, {22, 26}, {23, 24}, {23, 26}, {24, 25}, {25, 26}. In total, there are 82 encodable patterns for any lifting factor Z=a2^{k} with a=9, BG1.

For a=11, it can be shown that the encodable patterns for BG1 with P={1, 2, c, d}, where {c, d} are one of: {3, 4}, {3, 5}, {3, 8}, {3, 9}, {3, 12}, {3, 13}, {3, 15}, {3, 17}, {3, 18}, {3, 22}, {3, 23}, {3, 24}, {3, 25}, {3, 26}, {4, 5}, {4, 6}, {4, 8}, {4, 9}, {4, 10}, {4, 15}, {4, 16}, {4, 18}, {4, 20}, {4, 24}, {4, 26}, {5, 6}, {5, 10}, {5, 12}, {5, 13}, {5, 16}, {5, 17}, {5, 20}, {5, 22}, {5, 23}, {5, 25}, {6, 8}, {6, 9}, {6, 12}, {6, 13}, {6, 15}, {6, 17}, {6, 18}, {6, 22}, {6, 23}, {6, 24}, {6, 25}, {6, 26}, {8, 10}, {8, 12}, {8, 13}, {8, 16}, {8, 17}, {8, 20}, {8, 22}, {8, 23}, {8, 25}, {9, 10}, {9, 12}, {9, 13}, {9, 16}, {9, 17}, {9, 20}, {9, 22}, {9, 23}, {9, 25}, {10, 12}, {10, 13}, {10, 15}, {10, 17}, {10, 18}, {10, 22}, {10, 23}, {10, 24}, {10, 25}, {10, 26}, {12, 15}, {12, 16}, {12, 18}, {12, 20}, {12, 24}, {12, 26}, {13, 15}, {13, 16}, {13, 18}, {13, 20}, {13, 24}, {13, 26}, {15, 16}, {15, 17}, {15, 20}, {15, 22}, {15, 23}, {15, 25}, {16, 17}, {16, 18}, {16, 22}, {16, 23}, {16, 24}, {16, 25}, {16, 26}, {17, 18}, {17, 20}, {17, 24}, {17, 26}, {18, 20}, {18, 22}, {18, 23}, {18, 25}, {20, 22}, {20, 23}, {20, 24}, {20, 25}, {20, 26}, {22, 24}, {22, 26}, {23, 24}, {23, 26}, {24, 25}, {25, 26}. In total, there are 119 encodable patterns for any lifting factor Z=a2^{k} with a=11, BG1.

For a=13, it can be shown that the encodable patterns for BG1 with P={1, 2, c, d}, where {c, d} are one of: {3, 4}, {3, 5}, {3, 8}, {3, 9}, {3, 12}, {3, 13}, {3, 15}, {3, 17}, {3, 18}, {3, 22}, {3, 23}, {3, 24}, {3, 25}, {3, 26}, {4, 5}, {4, 6}, {4, 8}, {4, 9}, {4, 10}, {4, 15}, {4, 16}, {4, 18}, {4, 20}, {4, 24}, {4, 26}, {5, 6}, {5, 10}, {5, 12}, {5, 13}, {5, 16}, {5, 17}, {5, 20}, {5, 22}, {5, 23}, {5, 25}, {6, 8}, {6, 9}, {6, 12}, {6, 13}, {6, 15}, {6, 17}, {6, 18}, {6, 22}, {6, 23}, {6, 24}, {6, 25}, {6, 26}, {8, 10}, {8, 12}, {8, 13}, {8, 16}, {8, 17}, {8, 20}, {8, 22}, {8, 23}, {8, 25}, {9, 10}, {9, 12}, {9, 13}, {9, 16}, {9, 17}, {9, 20}, {9, 22}, {9, 23}, {9, 25}, {10, 12}, {10, 13}, {10, 15}, {10, 17}, {10, 18}, {10, 22}, {10, 23}, {10, 24}, {10, 25}, {10, 26}, {12, 15}, {12, 16}, {12, 18}, {12, 20}, {12, 24}, {12, 26}, {13, 15}, {13, 16}, {13, 18}, {13, 20}, {13, 24}, {13, 26}, {15, 16}, {15, 17}, {15, 20}, {15, 22}, {15, 23}, {15, 25}, {16, 17}, {16, 18}, {16, 22}, {16, 23}, {16, 24}, {16, 25}, {16, 26}, {17, 18}, {17, 20}, {17, 24}, {17, 26}, {18, 20}, {18, 22}, {18, 23}, {18, 25}, {120, 22}, {120, 23}, {20, 24}, {20, 25}, {20, 26}, {22, 24}, {22, 26}, {23, 24}, {23, 26}, {24, 25}, {25, 26}. In total, there are 119 encodable patterns for any lifting factor Z=a2^{k} with a=13, BG1.

Finally, for a=15, it can be shown that the encodable patterns for BG1 with P={1, 2, c, d}, where {c, d} are one of: {3, 4}, {3, 5}, {3, 9}, {3, 12}, {3, 13}, {3, 15}, {3, 17}, {3, 23}, {3, 24}, {3, 25}, {3, 26}, {4, 6}, {4, 16}, {4, 18}, {4, 24}, {5, 6}, {5, 12}, {5, 16}, {5, 23}, {5, 25}, {6, 12}, {6, 13}, {6, 15}, {6, 17}, {6, 18}, {6, 23}, {6, 24}, {6, 26}, {8, 10}, {8, 12}, {8, 13}, {8, 16}, {8, 17}, {8, 23}, {8, 25}, {9, 10}, {9, 16}, {9, 17}, {9, 20}, {9, 23}, {9, 25}, {10, 12}, {10, 13}, {10, 18}, {10, 23}, {10, 24}, {10, 25}, {12, 16}, {12, 18}, {12, 20}, {13, 15}, {13, 16}, {13, 18}, {13, 20}, {13, 24}, {13, 26}, {15, 23}, {15, 25}, {16, 17}, {16, 23}, {16, 24}, {16, 25}, {16, 26}, {17, 18}, {18, 20}, {18, 23}, {20, 23}, {20, 24}, {23, 26}, {25, 26}. In total, there are 70 encodable patterns for any lifting factor Z=a2^{k} with a=15, BG1.

The encodable patterns for BG2 will now be discussed in more detail. For example, it can be shown that the encodable patterns for BG2 with a=2 and with P={1, 2, c, d}, where {c, d} are one of: {c, d} being one of {3, 7}, {3, 10}, {3, 13}, {3, 14}, {5, 7}, {5, 10}, {5, 13}, {5, 14}, {7, 9}, {7, 12}, {9, 10}, {9, 13}, {9, 14}, {10, 12}, {12, 13}, {12, 14}. In total, there are 16 encodable patterns for any lifting factor Z=a2^{k} with a=2, BG2.

Similarly, it can be shown that the encodable patterns for BG2 with a=3 and with P={1, 2, c, d}, where {c, d} are one of: {3, 10}, {3, 13}, {3, 14}, {5, 10}, {5, 13}, {9, 10}, {9, 13}, {9, 14}, {10, 12}, {12, 13}, {12, 14}. In total, there are 11 encodable patterns for any lifting factor Z=a2^{k} with a=3, BG2.

In addition, it can be shown that the encodable patterns for BG2 with a=5 and with P={1, 2, c, d}, where {c, d} are one of: {3, 7}, {3, 13}, {3, 14}, {5, 7}, {5, 10}, {5, 13}, {5, 14}, {7, 9}, {7, 12}, {19, 13}, {9, 14}, {10, 12}, {12, 13}, {112, 14}. In total, there are 14 encodable patterns for any lifting factor Z=a2^{k} with a=5, BG2.

Moreover, it can be shown that the encodable patterns for BG2 with a=7 and with P={1, 2, c, d}, where {c, d} are one of: {3, 7}, {3, 10}, {3, 13}, {5, 7}, {5, 10}, {5, 13}, {5, 14}, {7, 9}, {7, 12}, {9, 10}, {9, 13}, {10, 12}. In total, there are 12 encodable patterns for any lifting factor Z=a2^{k} with a=7, BG2.

Similarly, it can be shown that the encodable patterns for BG2 with a=9 and with P={1, 2, c, d}, where {c, d} are one of: {3, 7}, {3, 13}, {3, 14}, {5, 7}, {5, 13}, {5, 14}, {7, 9}, {7, 12}, {9, 13}, {9, 14}, {10, 12}. In total, there are 11 encodable patterns for any lifting factor Z=a2^{k} with a=9, BG2.

For a=11, it can be shown that the encodable patterns for BG2 with P={1, 2, c, d}, where {c, d} are one of: {3, 7}, {3, 10}, {3, 13}, {3, 14}, {5, 7}, {5, 10}, {5, 13}, {5, 14}, {7, 9}, {7, 12}, {9, 10}, {9, 13}, {9, 14}, {10, 12}, {12, 13}, {12, 14}. In total, there are 16 encodable patterns for any lifting factor Z=a2^{k} with a=11, BG2.

For a=13, it can be shown that the encodable patterns for BG2 with P={1, 2, c, d}, where {c, d} are one of: {3, 7}, {3, 10}, {3, 13}, {3, 14}, {5, 7}, {5, 10}, {5, 13}, {5, 14}, {7, 9}, {7, 12}, {9, 10}, {9, 13}, {9, 14}, {10, 12}, {12, 13}, {12, 14}. In total, there are 16 encodable patterns for any lifting factor Z=a2^{k} with a=13, BG2.

Finally, for a=15, it can be shown that the encodable patterns for BG2 with P={1, 2, c, d}, where {c, d} are one of: {3, 10}, {3, 13}, {5, 10}, {5, 13}, {7, 9}, {9, 10}, {9, 13}, {9, 14}, {12, 13}, {12, 14}. In total, there are 10 encodable patterns for any lifting factor Z=a2^{k} with a=15, BG2.

The number of encodable patterns for each Z class for BG1 is denoted herein as a function N₁(a) since it depends upon the integer multiplier a. Similarly, the number of encodable patterns for each Z class for BG2 is denoted as a function N₂(a) since it also depends upon the integer multiplier a. With this nomenclature in mind, the number of encodable patterns for each Z class for BG1 will be summarized in the following Table 1:

TABLE 1

| a | N1(a) |
|---|---|
| 2 | 119 |
| 3 | 88 |
| 5 | 112 |
| 7 | 91 |
| 9 | 82 |
| 11 | 119 |
| 13 | 119 |
| 15 | 70 |

Similarly, the number of encodable patterns for each Z class for BG2 is given by the following Table 2:

TABLE 2

| a | N₂(a) |
|---|---|
| 2 | 16 |
| 3 | 11 |
| 5 | 14 |
| 7 | 12 |
| 9 | 11 |
| 11 | 16 |
| 13 | 16 |
| 15 | 10 |

Although the number of encodable patterns may be relatively large, a proper choice of the set P for a given Z class leads to a significant reduction of computation complexity for determining the core parity bits (note that the determination of the extension parity bits is a relatively trivial exercise due to the main diagonal structure for the extension parity bit columns). The following discussion will be directed to the determination of the core parity bits for any given encodable pattern, but it will be appreciated that the number of calculations in this determination is markedly reduced by the proper selection of the set P.

The determination of the core parity bits uses only the core of the base graph. The resulting lifting by the lifting factor Z forms a lifted core parity-check matrix. Each element in the core of the base graph is then replaced by a Z×Z permutation matrix. A zero element is replaced by a Z×Z matrix of all zeroes. A unit element (equal to 1) is replaced by the identity Z×Z matrix. As an element increments from unity, the identity matrix is cyclically shifted accordingly from the identity matrix to form the corresponding Z×Z permutation matrix. As used herein, the term “permutation matrix” thus refers only to the identity Z×Z matrix or cyclic shifts of the identity Z×Z matrix. The permutation matrix can thus be represented as Pⁱ, where Pⁱ is the Z×Z permutation matrix such that, for each column index j∈{0, 1, . . . , Z−1}, the j+i mod Z)th element of that column is 1. All the remaining column elements are zero. If the element being replaced by the Z×Z permutation matrix is in an information-bit column, the element is multiplied by Z corresponding information bits during the LDPC encoding. It is computationally efficient to represent these Z information bits and the permutation matrices by corresponding binary polynomials. With regard to forming a binary polynomial, consider, for example, a binary word 1001. A binomial polynomial of such a word is the binary vector x³+0*x²+0*x+1. It can be shown that the modulo multiplication of a binary polynomial with a monomial xⁱ is equivalent to a cyclic shift of the binary polynomial by i, where i is a positive integer.

Quasi-cyclic LDPC codes, or cyclically lifted LDPC codes, with a lifting factor Z, can be viewed as codes over the ring [symbol] (x) of binary polynomials modulo x^{Z}+1. With that binary polynomial convention in mind, the core of BG1 or BG2 may be represented by a matrix H that is of size 4 rows by r columns, where r is 26 for BG1 and r is 14 for BG2. From the matrix H, a matrix H(x) is the lifted matrix over the ring [symbol] (x) such that H_{i,j}(x)=x^{H}^{_{i,j}} if H_{i,j} is not equal to −1 and H_{i,j}(x)=0 if H_{i,j} is equal to −1. Given the set P, the corresponding parity-bit columns of H(x) form a submatrix denoted herein as H_{P}(x). Let the set I be formed by the column indices of the information-bit columns in H(x). The submatrix formed by these information-bit columns may thus be denoted as H_{f}(x). In the following discussion, H_{f}(x) is also denoted as a first submatrix whereas H_{P}(x) is denoted as a second submatrix. The codeword produced by the systematic encoding is denoted herein as C(x), where C(x) satisfies H(x)C(x)=0 and includes Cᵣ(x) information bits and C_{P}(x) core parity bits. The multiplication of the information-bit column submatrix H_{f}(x) with Cᵣ(x) produces a syndrome vector S(x). The syndrome S(x) may be used to calculate the core parity bits through the following Equation (1)

H_{P}(x)C_{P}(x)=S(x) Eq. (1)

Through the application of row operations, Eq. (1) may be transformed into the following Equation (2)

G_{P}(x)C_{P}(x)=S(x) Eq. (2)
where, through the row operations, G_{P}(x) is derived from H_{P}(x) and a transformed syndrome \tilde{S}(x) is derived from S(x). The matrix G_{P}(x) is also denoted herein as a third submatrix. The transformed syndrome \tilde{S}(x) includes a last element that equals P^{T}(x)S(x), where P(x) is a column vector. Through the row operations, H_{P}(x) is transformed into G_{P}(x) such that G_{P}(x) is an upper triangular matrix to facilitate the systematic encoding. A typical upper triangular form for the matrix G_{P}(x) is as follows:

$${G}_{P} ( x ) = ( \begin{matrix}{x}^{a} & 0 & 0 & {G}_{a} ( x ) \\ 0 & {x}^{b} & 0 & {G}_{b} ( x ) \\ 0 & 0 & {x}^{c} & {G}_{c} ( x ) \\ 0 & 0 & 0 & Q ( x )\end{matrix} ) \qquad Eq . ( 3 )$$

where a, b, and c are integers selected from the set of {0, 1, . . . , Z−1} and Gₐ(x), G_{b}(x), and G_{c}(x) are binary polynomials (or monomials). With the lifting factor Z specified, a solution can be found for G_{P}(x) that depends only on the lifting factor Z. The polynomial Q(x) is such that the following Equation (4) is satisfied:

Q(x)C(x)=P(x)^{T}S(x) Eq. (4)
where C(x) is the last element in C_{P}(x). Once C(x) is thus determined, the remainder of C_{P}(x) is readily determined from Eq. (3) through back substitution.

The selection of the set P should ensure that the inverse of Q(x) (denoted as Q⁻¹(x)) exists such that the following Equation (5) is satisfied

C(x)=Q⁻¹(x)P^{T}(x)S(x) Eq (5)

A proper selection of the set P will not only ensure that Q⁻¹(x) satisfies Eq. (5) but that also Gₐ(x), G_{b}(x), and G_{c}(x) are each a binary monomial or a binary polynomial of relatively few terms. In addition, the proper selection of the set P allows the factorization of Q⁻¹(x) as follows:

Q⁻¹(x)=R(x)Πₖ₌₀^{κ-1} Q(x^{y}) Eq. (6)
where y=2^{k}, κ is a relatively small integer, and R(x) is a sparse polynomial (i.e., like Q(x), R(x) should have as few terms as possible).

The proper selection of the set P thus produces a sparse R(x) and Q(x). This selection may be based upon the largest Z for each Z class. For example, suppose that Eq. (6) is solved for the largest value of Z in a given Z class. The corresponding Q inverse function may be denoted as Q_{Z}⁻¹(x). The transformation of Eq. (6) for a smaller Z is obtained by a modulo operation on the solution of Eq. (6) for the largest value of Z. For example, if Eq. (6) is solved for the largest Z, the solution for a smaller Z such as Z/2 would be the modulo operation mod x^{Z/2}+1 on this largest Z solution. Thus, if a selection of the set P leads to a relatively simple solution for the largest Z in a Z class, that same selection of P will lead to simple solutions for the remaining values of Z in the Z class.

The selection of a suitable set P for each Z class for BG1 and the corresponding R(x), Q(x), and κ will now be summarized. For the Z class of a=2 (the largest Z being 256), the selection of P={1, 2, 25, 26} results in Q(x)=x²+x⁴+x³⁶+x¹⁰⁶+x¹²¹, R(x)=1+x³²+x¹⁶⁰+x¹⁹²+x²²⁴, and κ=5. For the Z class of a=3 (the largest Z being 384), the selection of P={1, 2, 24, 25} results in Q(x)=x⁵⁵+x⁷⁶+x²⁰⁵+x²⁰⁸+x³⁰⁷, R(x)=x³⁵², and κ=5. For the Z class of a=5 (the largest Z being 320), the selection of P={1, 2, 25, 26} results in Q(x)=x⁶⁵+x⁶⁸+x²²⁰+x²⁶⁶+x³⁰³, R(x)=x²⁵⁶, and κ=6. For the Z class of a=7 (the largest Z being 224), the selection of P={1, 2, 25, 26} results in Q(x)=x+x¹⁴¹+x¹⁸⁶+x²⁰¹+x²⁰⁷, R(x)=x⁶⁴, and κ=5. For the Z class of a=9 (the largest Z being 288), the selection of P={1, 2, 24, 25} results in Q(x)=x¹⁷⁹+x²⁰⁹+x²¹¹+x²⁴⁰+x²⁵⁸, R(x)=x⁴⁸+x¹¹²+x²⁰⁸+x²⁴⁰+x²⁷², and κ=4. For the Z class of a=11 (the largest Z being 352), the selection of P={1, 2, 24, 25} results in Q(x)=x³⁸+x⁷⁷+x¹²¹+x²²⁶+x²⁹⁴, R(x)=x¹⁶+x⁴⁸+x¹²+x¹⁴⁴+x²⁷²+x³⁰⁴+x³³⁶, and κ=3. For the Z class of a=13 (the largest Z being 208), the selection of P={1, 2, 24, 25} results in Q(x)=1+x²²+x³⁵+x¹³²+x²⁰⁶, R(x)=1+x¹⁶+x³²+x⁸⁰+⁹⁶+x¹¹²+x¹²⁸+x¹⁷⁶+x¹⁹², and κ=4. For the Z class of a=15 (the largest Z being 240), the selection of P={1, 2, 25, 26} results in Q(x)=x⁹⁶+x¹²⁸+x¹⁵²+x¹⁷¹+x¹⁸⁹, R(x)=x¹⁶+x³²+x⁴⁸+x⁹⁶+x¹¹²+x¹⁶⁰+x¹⁹²+x²⁰⁸+x²²⁴ and κ=4.

The selection of a suitable set P for each Z class for BG2 and the corresponding R(x), Q(x), and x will now be summarized. For the Z class of a=2 (the largest Z being 256), the selection of P={1, 2, 12, 13} results in Q(x)=x⁹+x⁸¹+x¹⁶⁷, R(x)=x², and κ=5. For the Z class of a=3 (the largest Z being 384), the selection of P={1, 2, 12, 13} results in Q(x)=x²⁵+x²⁷+x¹⁷⁴, R(x)=x¹²⁸, and κ=7. For the Z class of a=5 (the largest Z being 320), the selection of P={1, 2, 12, 13} results in Q(x)=1+x²⁰+x¹³⁷, R(x)=x⁴⁸, and κ=4. For the Z class of a=7 (the largest Z being 224), the selection of P={1, 2, 9, 13} results in Q(x)=x²⁰+x⁵³+x⁸²+x⁹³+x¹⁵², R(x)=1+x³²+x¹¹²+x¹²⁸+¹⁶⁰+x¹⁷⁶+x¹⁹², and κ=4. For the Z class of a=9 (the largest Z being 288), the selection of P={1, 2, 5, 13} results in Q(x)=x¹⁹+x⁸³+x⁹⁵+x¹⁷⁹+x¹⁸⁵, R(x)=x⁴⁸+x¹¹²+x¹⁴⁴+x¹⁷⁶+x²⁰⁸, and κ=4. For the Z class of a=11 (the largest Z being 352), the selection of P={1, 2, 5, 13} results in Q(x)=x¹⁷+x⁹⁸+x¹⁸¹+x³⁰⁷+x³²⁶, R(x)=1+x⁶⁴+x⁹⁶+x¹⁶⁰+x²²⁴+x²⁵⁶+x³²⁰, and κ=5. For the Z class of a=13 (the largest Z being 208), the selection of P={1, 2, 12, 14} results in Q(x)=x³⁵+x⁷⁹+x¹²⁶+x¹⁶⁰+x¹⁶², R(x)=1+x³²+x⁴⁸+x⁶⁴+x⁹⁶+x¹²⁸+x¹⁹², and κ=4. For the Z class of a=15 (the largest Z being 240), the selection of P={1, 2, 3, 13} results in Q(x)=x⁵+x³⁴+x⁴²+x¹⁰²+x¹¹⁰, R(x)=x¹⁷⁶, and κ=5.

Referring again to Eq (6), the factorization of Q⁻¹(x) is quite advantageous in reducing the computation complexity of solving for C(x) using Eq. (5). In particular, Q⁻¹(x) is typically a dense polynomial, i.e., it contains numerous terms. For example, consider the Z class a=11 for BG1. As noted in Table 3, there are 119 encodable patterns for this Z class. For these 119 encodable patterns, the corresponding (sorted) number of terms for Q⁻¹(x) corresponding to the largest Z=352 are as follows: {151, 153, 157, 159, 159, 161, 161, 161, 161, 161, 161, 163, 163, 163, 163, 165, 165, 165, 165, 167, 167, 167, 167, 167, 169, 169, 169, 169, 169, 169, 169, 169, 171, 171, 171, 171, 171, 171, 171, 171, 173, 173, 173, 173, 173, 173, 173, 173, 173, 173, 173, 175, 175, 175, 175, 175, 175, 175, 175, 175, 177, 177, 177, 177, 177, 177, 177, 177, 177, 177, 179, 179, 179, 179, 179, 179, 179, 179, 181, 181, 181, 181, 181, 181, 181, 181, 181, 183, 183, 183, 183, 183, 183, 183, 185, 185, 185, 185, 187, 187, 187, 189, 189, 189, 189, 189, 189, 189, 189, 191, 191, 191, 191, 193, 193, 193, 195, 195, 195}. Given this voluminous number of terms, the multiplication of each term of the unfactorized Q⁻¹(x) with the polynomial P^{T}(x)S(x) then requires numerous cyclic shifts of the polynomial P^{T}(x)S(x), one for each term of the unfactorized Q⁻¹(x). In contrast, Q(x) is relatively sparse and thus has relatively few terms. Since R(x) is also sparse, the multiplication of the polynomial P^{T}(x)S(x) with the factorized form of Q⁻¹(x) results in relatively few cyclic shifts of the polynomial P^{T}(x)S(x). This reduction in computation complexity in general will depend upon the selection of the set P from the possible encodable patterns. Using the number of cyclic shifts as a proxy for computation complexity, it can be shown that the following selections of the set P for a given Z class of either BG1 or BG2 result in advantageously reduced computation complexity. For example, the following Table 3 lists again an optimal set P for each Z class for BG1:

TABLE 3

| a | k | largest Z | P | N_{g} | Nₛ |
|---|---|---|---|---|---|
| 2 | 7 | 256 | {1, 2, 25, 26} | 121 | 30 |
| 3 | 7 | 384 | {1, 2, 24, 25} | 59 | 26 |
| 5 | 6 | 320 | {1, 2, 25, 26} | 157 | 31 |
| 7 | 5 | 224 | {1, 2, 25, 26} | 89 | 26 |
| 9 | 5 | 288 | {1, 2, 24, 25} | 153 | 25 |
| 11 | 5 | 352 | {1, 2, 24, 25} | 195 | 22 |
| 13 | 4 | 208 | {1, 2, 24, 25} | 101 | 29 |
| 15 | 4 | 240 | {1, 2, 25, 26} | 115 | 29 |

where Ng is the number of cyclic shifts used if the unfactorized form of Q⁻¹(x) is used and Ns is the number of cyclic shifts for the calculations using the factorized form of Q⁻¹(x). It can be seen that the factorization of Q⁻¹(x) reduces the number of cyclic shifts by at least 70% for each Z class. A similar reduction in computation complexity can be seen for each Z class of BG2 as shown in the following Table 4:

TABLE 4

| a | k | largest Z | P | N_{g} | Nₛ |
|---|---|---|---|---|---|
| 2 | 7 | 256 | {1, 2, 12, 13} | 71 | 16 |
| 3 | 7 | 384 | {1, 2, 12, 13} | 185 | 22 |
| 5 | 6 | 320 | {1, 2, 12, 13} | 81 | 13 |
| 7 | 5 | 224 | {1, 2, 9, 13} | 113 | 27 |
| 9 | 5 | 288 | {1, 2, 5, 13} | 69 | 25 |
| 11 | 5 | 352 | {1, 2, 5, 13} | 189 | 32 |
| 13 | 4 | 208 | {1, 2, 12, 14} | 117 | 27 |
| 15 | 4 | 240 | {1, 2, 3, 13} | 85 | 21 |

The polynomials R(x), Q(x), and Q⁻¹(x) are all elements in [symbol] (x) and thus depend on the lifting factor Z. It thus can be shown the determination of C_{P}(x) can be based on Q_{z}(x), the inverse of Q(x) for the largest value of Z in a Z class. For example, suppose that Eq. (6) is solved for the largest value of Z in a given Z class. The transformation of Eq. (6) for a smaller Z is obtained by a modulo operation on the solution of Eq. (6) for the largest value of Z. For example, if Eq. (6) is solved for the largest Z, the solution for a smaller Z such as Z/2 would be the modulo operation mod x^{Z/2}+1 on this largest Z solution.

Referring again to Eq. (5), the binomial polynomial S(x) is readily calculated by the encoder through the multiplication of the information-bit column submatrix H(x) with the information bit portion C(x) of the codeword. The factorized Q⁻¹(x) and the vector P^{T}(x) depend upon the Z class and the base graph selection (either BG1 or BG2) and thus may be calculated offline and stored in the encoder. The stored and factorized Q⁻¹(x) may be derived using the largest lifting factor Z for the corresponding Z class. This polynomial is denoted as Q_{Z}⁻¹(x) as noted earlier. Should a smaller Z be used, the encoder may readily perform the appropriate modulo operation on the stored and factorized Q_{Z}⁻¹(x) to get the factorized Q⁻¹(x) for the smaller Z. From the factorized Q⁻¹(x) and the vector P^{T}(x), the encoder may perform the corresponding number of cyclic shifts on S(x) to derive C(x), the Z core parity bits corresponding to the first column of the base graph. With C(x) calculated, the encoder may then use G_{P}(x) as derived from H_{P}(x) to determine the remaining 3Z core parity bits through back substitution. After the encoding of the 4Z core parity bits, the encoder may generate whatever extension parity bits are necessary. Since the calculation of the extension parity bits is trivial due to the selection of either BG1 or BG2, their calculation will not be discussed further herein. A systematic LDPC encoder is thus provided that advantageously retains the LDPC base graph structure without the puncturing of information bits. A transmitter including a systematic LDPC encoder will now be discussed.

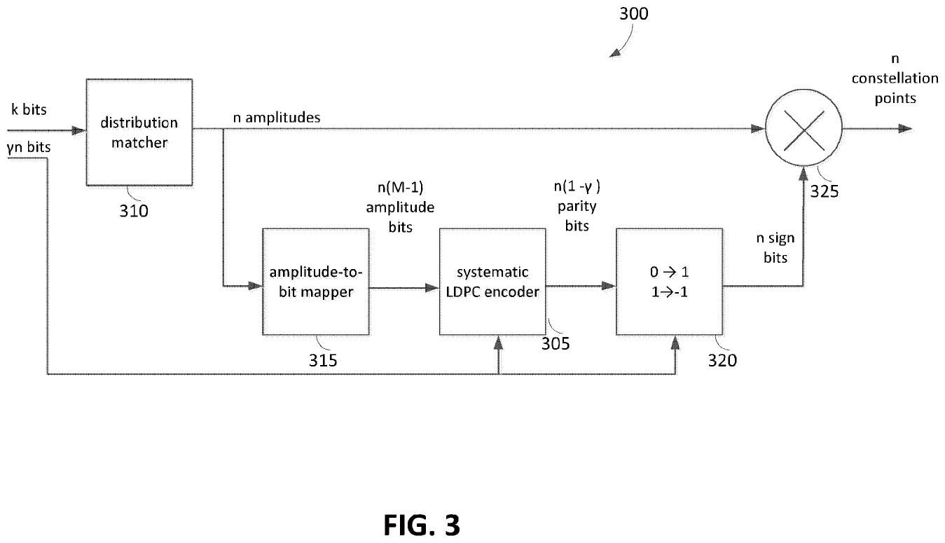

An example transmitter 300 including a systematic LDPC encoder 305 is shown in FIG. 3. A digital baseband source (not illustrated) provides k bits to a probabilistic amplitude shaping distribution matcher 310, where k is a plural positive integer. Distribution matcher 310 generates n amplitudes from the k bits, where n is a plural positive integer. In one implementation, distribution matcher 310 may generate the n amplitudes according to a 2^{M}-ary amplitude-shift-keyed (ASK) modulation, where M is a positive plural integer relating to the modulation order. An amplitude-to-bit mapper 315 maps each amplitude into M−1 amplitude bits. There are thus n(M−1) amplitude bits provided to systematic LDPC encoder 305. These amplitude bits are the information bits for LDPC encoder 305. Should BG1 be selected, the quantity n(M−1) may equal 22*Z although this need not be exact as accommodated through padding of information bits. Similarly, if BG2 is selected, the quantity n(M−1) may equal 10*Z.

In transmitter 300, there are n amplitudes so the ASK phasing of each amplitude requires n parity bits. In this ASK phasing, a binary zero parity bit may be mapped in a mapper 320 to a 0-degree (multiplication by 1) phase whereas a binary one parity bit may be mapped to a 180-degree (multiplication by −1) phase. A mixer 325 mixes each amplitude with its phase to produce n constellation points. Depending upon needs such as rate matching, the baseband source that generated the k bits may also generate γn parity bits. Should γ be zero, systematic LDPC encoder 305 generates the n parity bits needed for the phasing of the n amplitudes. However, because of the puncturing of the parity bits corresponding to the first two columns of the base graph, systematic LDPC encoder 305 actually generates n+2Z parity bits although the 2Z parity bits are punctured and thus not used for the amplitude phasing. If γ is non-zero, systematic LDPC encoder 305 generates n(1−γ) parity bits (not counting the 2Z parity bits that are punctured). Transmitter 300 may be included in a communication device such as either a UE 106 or a base station 108 in wireless communication system 100 that performs the systematic encoding of 5G LDPC.

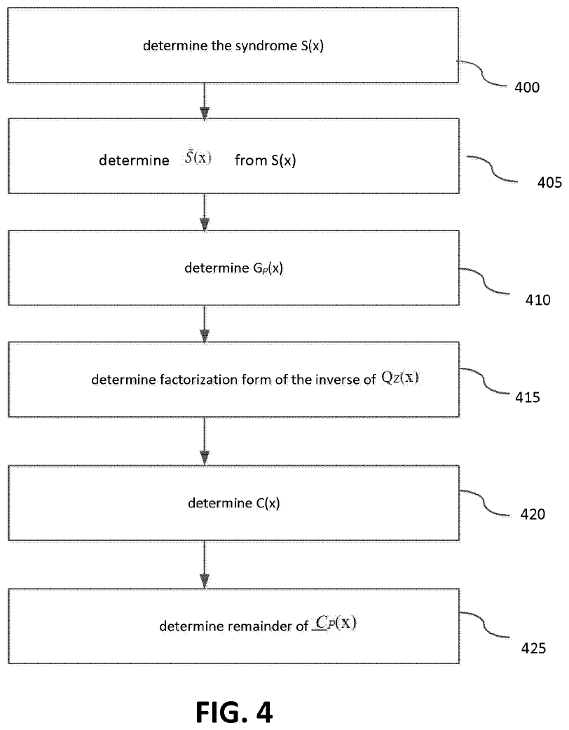

With the selection of BG1 or BG2 and also the appropriate lifting factor Z being provided, systematic LDPC encoder 305 may proceed as summarized in the flowchart of FIG. 4. Since the base graph H(x), the set P, and the lifting factor Z are all known, the information-bit column submatrix H_{f}(x) and the information-bit codeword Cᵣ(x) are also known. By multiplying H_{f}(x) with Cᵣ(x), the encoder may determine the syndrome S(x) in an act 400. From S(x), the encoder may then determine the transformed syndrome \tilde{S}(x) in an act 405. This determination may be based upon each possible value of lifting factor Z such that encoder 305 has the transformation procedure for each lifting factor Z value stored and proceeds accordingly to perform act 405. Alternatively, the encoder 305 may store the procedure for the largest Z in each Z class and thus calculate the corresponding largest-Z \tilde{S}(x). Should the encoder be using a smaller value of Z in a particular Z class, the encoder may determine each element of the smaller-Z \tilde{S}(x) by a modulo x^{Z}+1 operation on each element of the largest-Z \tilde{S}(x). With S(x) determined and the set P being known, the encoder may transform H_{P}(x) to determine G_{P}(x) in an act 410. Note that act 410 is optional as the encoder may store the matrix G_{P}(x) for the largest Z in the Z class. For example, suppose that BG1 is the core matrix and that the matrix G_{P}(x) for the largest Z (largest 352 for a=11) is stored. In that case, the encoder need not perform an online transformation to get G_{P}(x) from the corresponding H_{P}(x). A G_{P}(x) for a smaller Z (a smaller lifting factor for the a=11 Z class) can be obtained by performing a modulo x^{Z}+1=x¹⁷⁶+1 operation on each element of G_{P}(x) for Z=352.

When a smaller lifting factor Z is used by the encoder, H_{f}(x) and Cᵣ(x) will be all with respect to that smaller lifting factor, so that a syndrome vector S(x) for this smaller lifting factor will be determined accordingly. To determine \tilde{S}(x) for this smaller lifting factor, the encoder may utilize a procedure of computing the \tilde{S}(x) for the largest Z in the Z-class but use \tilde{S}(x) for the smaller lifting factor as an input to the procedure. Then, a modulo x^{Z}+1 operation is performed on the resulting \tilde{S}(x); which provides the \tilde{S}(x) for the smaller lifting factor z.

Both acts 405 and 410 occur according to the same set of row operations as discussed previously with respect to Eqs. (2) and (3). With G_{P}(x) being determined, the polynomial Q(x) is known. From Q(x), Q⁻¹(x) may be derived in the factorization form of Eq. (6) in an act 415. Note that the encoder may store a factorized form of Q_{Z}⁻¹(x) for the largest Z in a Z class and obtain a factorized form of Q⁻¹(x) for a smaller value of Z by a modulo Z operation on the exponents of the terms in the factorized form of Q_{Z}⁻¹(x). In this fashion, a well-factorized form of Q_{Z}⁻¹(x) ensures that a similarly well-factorized form of Q⁻¹(x) may be derived for a smaller value of Z. The encoder may then derive C(x) (the last element of C_{P}(x)) in an act 420. With C(x) determined, the encoder may then solve for the remaining elements of C_{P}(x) through back substitution of Eq. (2) in an act 425. The 4Z core parity bits are thus determined. Referring again to transmitter 300, the number of additional extension parity bits to be determined by encoder 305 depends upon the number n of the amplitudes to be phased. With the n parity bits determined, the encoding is completed and may begin again when a subsequent k input bits are provided to distribution matcher 310.

With regard to the modulo Z operation on the factors of the factorized form of Q_{Z}⁻¹(x) for the largest Z in a Z class to provide the factors for a smaller Z in the same Z class, the resulting smaller-Z factors may be used to determine the last element of C(x) for this smaller Z by multiplying the smaller-Z factors with the last element of \tilde{S}(x). The remaining elements of C(x) may then be determined through back substitution on G_{P}(x) and the other elements of \tilde{S}(x) for the smaller Z. It may thus be appreciated that a selection of the set P that results in relatively few terms for the factorization of Q_{Z}⁻¹(x) for the largest Z in a Z class guarantees that the same efficient encoding exists for the remaining members of the Z class.

An example of encoding for a particular Z class will now be discussed. For example, suppose that the Z class corresponds to a=11 and that BG1 is selected. As given by Table 3, the largest possible value of Z for that Z class is 352 and the set P is {1, 2, 24, 25}. The base graph may thus be lifted by a lifting factor of 352 to provide the core parity-check matrix. Note that this lifting may be performed offline such that the encoder would be pre-configured with the largest Z lifted version of the base graphs for each Z class. Alternatively, this lifting may be performed by the encoder. With the parity-bit columns and information-bit columns being identified, the encoder may then use the submatrix H(x) of the information-bit columns from the parity-check matrix to multiply this submatrix HX(x) with the information bits to provide the syndrome S(x). The encoder may further be configured with the transformed version of H_{P}(x), G_{P}(x). In this example, the element at the intersection of the fourth row and fourth column of G_{P}(x) is the polynomial Q(x)=x³⁸+x⁷⁷+x¹²¹+x²²⁶+x²⁹⁴. The matrix G_{P}(x) is as follows:

$${G}_{P} ( x ) = ( \begin{matrix}1 & 0 & 0 & {x}^{77} + {x}^{121} + {x}^{294} \\ 0 & 1 & 0 & {x}^{121} + {x}^{294} \\ 0 & 0 & {x}^{94} & {x}^{97} \\ 0 & 0 & 0 & Q ( x )\end{matrix} )$$

The transformed \tilde{S}(x) is as follows:

$$\tilde{S} ( x ) = ( \begin{matrix}{S}_{0} ( x ) + {S}_{1} ( x ) + {x}^{24} {S}_{3} ( x ) \\ {S}_{0} ( x ) + {x}^{24} {S}_{3} ( x ) \\ {S}_{3} ( x ) \\ {P}^{T} ( x ) S ( x )\end{matrix} )$$

where S₀(x), S₁(x), S₂(x), and S₃(x) are the four elements of S(x) and where P^{T}(x) is (1, 1, 1, x²⁴+x²⁹³) The factorization of Q(x) gives Q⁻¹(x)=R(x)Q(x)Q(x²)Q(x⁴), where R(x) equals x¹⁶+x⁴⁸+x¹¹²+x¹⁴⁴+x²⁷²+x³⁰⁴+x³³⁶. As given above, Q(x) has five monomial terms. Thus Q(x²) and Q(x⁴) each has five monomial terms as well. R(x) has 7 monomial terms. Thus, the multiplication of P^{T}(x)S(x) by the factorized Q⁻¹(x) leads to 7+3*5=22 cyclic shifts of P^{T}(x)S(x). This is considerably fewer cyclic shifts as compared to the 195 cyclic shifts (see Table 3) that would be required if P^{T}(x)S(x) were instead multiplied by the unfactorized Q⁻¹(x).

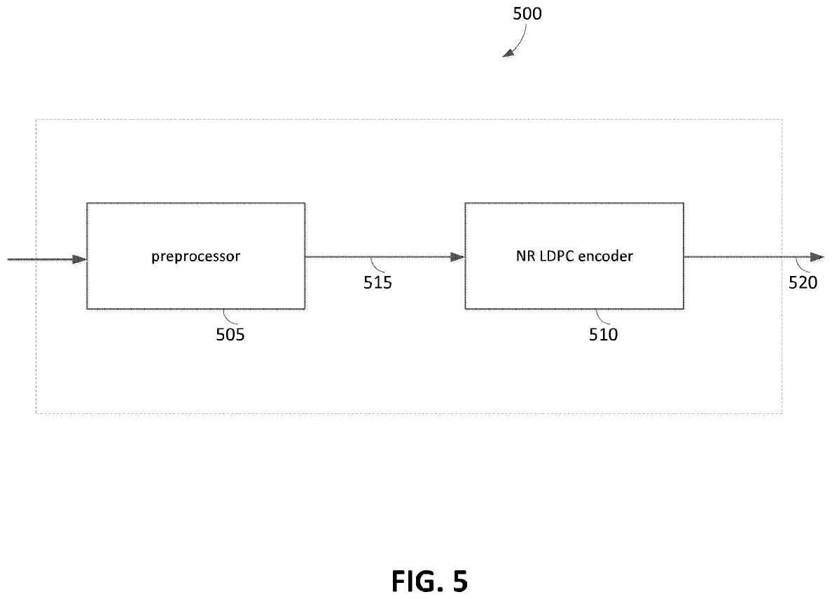

Referring again to transmitter 300, encoder 305 may be modified so that a conventional 5G LDPC encoder may still be included in the transmit chain. For example, encoder 305 may be modified to form a preprocessor 505 in a systematic LDPC encoder 500 shown in FIG. 5. Preprocessor 505 functions as discussed with respect to encoder 305 except that only the first two core parity bits (and possibly the remaining two core parity bits as well) need be generated in an intermediate codeword 515. An NR LDPC encoder 510 configured with the same base graph and lifting factor as employed in preprocessor 505 processes the intermediate codeword 515 to produce an output codeword 520. Analogous to transmitter 300, the parity bits in the output codeword 520 may then be used to phase the amplitudes in a transmitter including systematic LDPC encoder 500 to form the amplitude constellation.

Suppose that BG1 is used in systematic LDPC encoder 500 and that the set P selected for preprocessor 505 is {1, 2, 24, 25}. Since NR LDPC encoder 510 functions in a conventional fashion, NR LDPC encoder 510 will process the first 22*Z bits in the intermediate codeword 515. It is known that the first 2Z bits of the intermediate codeword 515 are going to be core parity bits. The Z core parity bits from the first column of the BG1 as processed in preprocessor 505 may be denoted as a whereas the Z core parity bits from the second column may be denoted as β. Each of columns 3 through 22 produces a corresponding set of Z information bits. The Z information bits from column 3 may be denoted as m3, the Z information bits from column 4 may be denoted as m4, and so on. Note that there is no need for preprocessor 505 to continue coding using any additional columns of the core parity-check matrix because NR LDPC encoder 510 will only encode the first 22Z bits of intermediate codeword 515. S₀ once preprocessor 505 has calculated for the first 2Z core parity bits, it is finished as any further encoding will not be used (at least for this example of P). Intermediate codeword 515 for this example will thus equal {α, β,m3, m4, . . . m22}. NR encoder 510 will then first generate 4Z “core parity bits” based upon this codeword. But in reality, what would ordinarily be the first 2Z core parity bits from NR encoder 510 are instead the regeneration of information bits m1 and m2. NR encoder 510 punctures α and β. The first 20Z bits in an output codeword 520 from NR encoder 510 will then be {m3, m4, . . . , m22}. This first 20Z bits may be represented herein as a variable M1. The first 24Z bits in the output codeword 520 will thus include M1 as well as the regenerated information bits m1 and m2. The exact location of where m1 and m2 are sequenced within this first 24Z bits depends upon the selection of the set P. For example, if P is {1, 2, 24, 25} as assumed above, the first 24Z bits in the output codeword 520 will be {M1, p23, m1, m2, p26}, where p23 and p26 are the final two 2Z core parity bits. There is thus no puncturing of information bits despite the use of NR encoder 510. NR encoder 510 also generates any needed extension parity bits so that the amplitudes may be phased.

More generally, preprocessor 505 will calculate the first 2Z core parity bits and also calculate the core parity bits corresponding to any of columns 3 through 22 (in the case of BG1 being selected) that are core parity-bit columns. Similarly, preprocessor 505 calculates the first 2Z core parity bits and also calculates the core parity bits corresponding to any of columns 3 through 10 (in the case of BG2 being selected) that are core parity-bit columns. NR encoder 510 regenerates the missing information bits and also generates the parity bits for the phasing of the amplitudes.

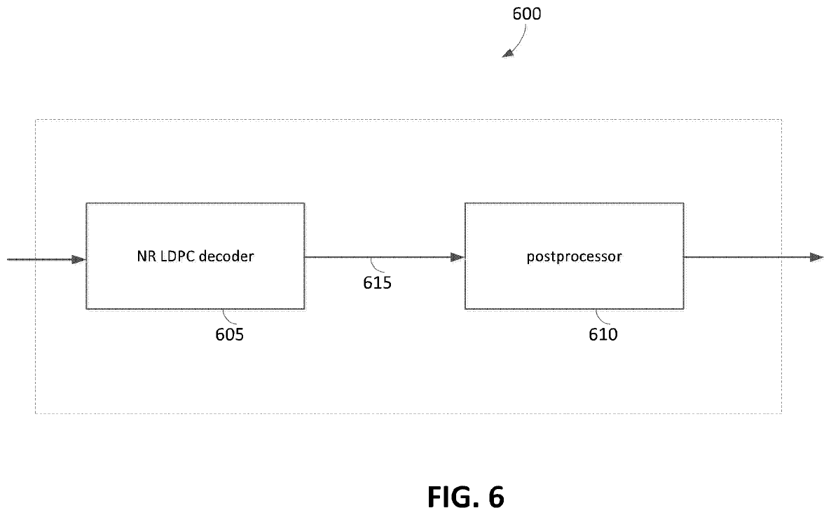

The decoding of a received version of output codeword 520 in a receive chain including an NR LDPC decoder is analogous as shown for a systematic LDPC decoder 500 of FIG. 6. For example, suppose that the BG1 is selected and that the setP is {1, 2, 24, 25} as discussed with regard to NR encoder 510. A decoded set of information bits from an NR LDPC decoder 605 would then be the set {m3, m4, . . . , m22, p23, m1, m2, p26}. A postprocessor 610 thus needs to merely shuffle these bits to provide the appropriate order of {m1, m2, . . . m21, m22} to a baseband processor.

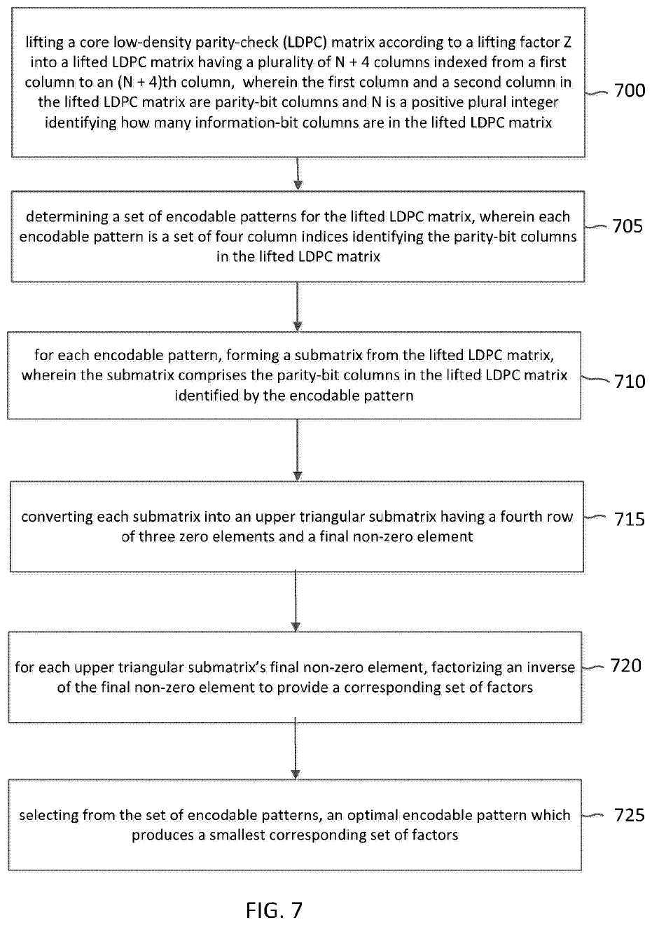

A method of selecting an optimal set P will now be discussed with respect to the flowchart of FIG. 7. This method may be performed by a general-purpose computer and includes an act 700 of lifting a core low-density parity-check (LDPC) matrix according to a lifting factor Z to form a lifted LDPC matrix having a plurality of N+4 columns indexed from a first column to an (N+4)th column, wherein the first column and a second column in the lifted LDPC matrix are parity-bit columns and N is a positive plural integer identifying how many information-bit columns are in the lifted LDPC matrix, and wherein the lifting factor Z is selected from a class of lifting factors that are all proportional to a positive plural integer a. An example of act 700 would be a lifting either of BG1 or BG2 by a lifting factor Z selected from a Z class. The method also includes an act 705 of determining a set of encodable patterns for the lifted LDPC matrix, wherein each encodable pattern is a set of four column indices identifying the parity-bit columns in the lifted LDPC matrix, and wherein the set of encodable patterns is the same for each lifting factor in the class of lifting factors. The determination of the encodable patterns as discussed earlier for a particular Z class of BG1 or BG2 is an example of act 705. As discussed previously, once a set of encodable patterns has been determined for one member of a Z class, the set of encodable patterns is correct for each member of the Z class. The method also includes an act 710 that is performed for each encodable pattern and includes forming a submatrix from the lifted LDPC matrix, wherein the submatrix comprises the parity-bit columns in the core LDPC matrix identified by the encodable pattern. The formation of the submatrix H_{P}(x) for each encodable pattern of a particular Z class is an example of act 710. In addition, the method includes an act 715 of converting each submatrix into an upper triangular submatrix having a fourth row formed by three zero elements and a final non-zero element. The formation of G_{P}(x) from H_{P}(x) for each encodable pattern of a particular Z class is an example of act 715. Furthermore, the method includes an act 720 that is performed for each upper triangular submatrix's final non-zero element and includes factorizing an inverse of the final non-zero element to provide a corresponding set of factors. The factorization of Q⁻¹(x) for each encodable pattern of a particular Z class is an example of act 720. Finally, the method includes an act 725 of selecting from the set of encodable patterns, an optimal encodable pattern which produces a smallest corresponding set of factors. The selection of the optimal set P as discussed with regard to Tables 3 and 4 with respect to a particular Z class is an example of act 725.

The disclosure will now be summarized in a series of clauses:
Clause 1. A wireless communication device, comprising:
   an encoder configured to encode a plurality of N*Z information bits into a codeword of (N+4)*Z bits according to a low-density parity-check matrix in which a first 2*Z bits of the codeword are parity bits and a subsequent (N+2)*Z bits of the codeword include the N*Z information bits and 2*Z additional parity bits, wherein N is a plural positive integer and Z is a lifting factor of the low-density parity-check matrix.
Clause 2. The wireless communication device of clause 1, wherein the encoder is included within a transmitter configured to puncture the first 2*Z bits of the codeword and to transmit the subsequent (N+2)*Z bits of the codeword.
Clause 3. The wireless communication device of any of clauses 1-2, wherein the low-density parity-check matrix is a lifted version according to Z of a base matrix selected from base graph 1 (BG1) or base graph 2 (BG2), and wherein a first two columns of the low-density parity-check matrix are parity-bit columns and a subsequent (N+2) columns of the low-density parity-check matrix include two additional parity-bit columns and N information-bit columns.
Clause 4. The wireless communication device of clause 3, wherein Z equals a product of a positive integer a and 2^{k}, wherein k is a function of the positive integer a and the positive integer a is selected from a set of {2, 3, 5, 7, 9, 11, 13, 15} and a set P identifies an index of each parity-bit column in the low-density parity-check matrix, and wherein the set P is a function of a and whether the base matrix is selected from BG1 or BG2.
Clause 5. The wireless communication device of clause 4, wherein the encoder is further configured to:
   calculate a product of a first submatrix from the low-density parity-check matrix with the plurality of N*Z information bits to provide a syndrome bit vector, wherein the first submatrix comprises the information-bit columns of the low-density parity-check matrix.
Clause 6. The wireless communication device of clause 5, wherein the encoder is further configured to:
   transform the syndrome bit vector to form a transformed syndrome bit vector according to a plurality of row operations that are configured to transform a second submatrix from the low-density parity-check matrix into a third submatrix having an upper triangular form, wherein the second submatrix comprises the four parity-bit columns of the low-density parity-check matrix; and
   multiply an inversion of a last element in a fourth row of the third submatrix with a last element of the transformed syndrome bit vector to determine a first set of Z parity bits corresponding to the first column of the low-density parity-check matrix.
Clause 7. The wireless communication device of clause 6, wherein the encoder is further configured to:
   calculate an additional 3*Z parity bits using back substitution on the third submatrix, wherein a first set of Z parity bits of the additional 3*Z parity bits correspond to the second column of the low-density parity-check matrix.
Clause 8. The wireless communication device of clause 6, wherein for a given value of the positive integer a there is a largest lifting factor, and Z is less than the largest lifting factor for the given value of the positive integer a and is also proportional to the given value of the positive integer a, and wherein the encoder is further configured to calculate the inversion of the last element in the fourth row of the third submatrix based upon a modulo operation on an inversion of a last element of a largest third submatrix corresponding to the largest lifting factor.
Clause 9. The wireless communication device of clause 6, wherein the encoder is further configured to calculate the inversion of the last element in the fourth row of the third submatrix based upon a factorization of the last element.
Clause 10. The wireless communication device of any of clauses 1-9, wherein the wireless communication device comprises a user equipment.
Clause 11. The wireless communication device of clause 4, wherein the low-density parity-check matrix is a lifted version of BG1, and wherein the set P comprises:
   {1, 2, 25, 26} for a=2;
   {1, 2, 24, 25} for a=3;
   {1, 2, 25, 26} for a=5;
   {1, 2, 25, 26} for a=7
   {1, 2, 24, 25} for a=9;
   {1, 2, 24, 25} for a=11;
   {1, 2, 24, 25} for a=13; and
   {1, 2, 25, 26} for a=15.
Clause 12. The wireless communication device of clause 4, wherein the low-density parity-check matrix is a lifted version of BG2, and wherein the set P comprises:
   {1, 2, 12, 13} for a=2;
   {1, 2, 12, 13} for a=3;
   {1, 2, 12, 13} for a=5;
   {1, 2, 9, 13} for a=7
   {1, 2, 5, 13} for a=9;
   {1, 2, 5, 13} for a=11;
   {1, 2, 12, 14} for a=13; and
   {1, 2, 3, 13} for a=15.
Clause 13. The wireless communication device of any of clauses 1-12, wherein the wireless communication device comprises a base station.
Clause 14. The wireless communication device of any of clauses 1-13, further comprising:
   a shaping encoder configured to encode a plurality of input bits into a plurality of M amplitudes according to a probabilistic amplitude shaping, wherein M is a plural positive integer; and
   an amplitude-to-bit mapper configured to encode the plurality of M amplitudes into the plurality of N*Z information bits.
Clause 15. The wireless communication device of clause 14, further comprising:
   a constellation mapper configured to map the plurality of M amplitudes into a plurality of M constellation symbols.
Clause 16. The wireless communication device of clause 1, further comprising: a second encoder configured to encode the first codeword according to a second low-density parity-check code into a second codeword in which a first (N+4)*Z bits of the second codeword include the N*Z information bits, wherein Z is also a lifting factor of the second low-density parity-check code.
Clause 17. The wireless communication device of clause 16, wherein the second low-density parity-check code is a new radio (NR) low-density parity-check code based upon a base graph 1 in which N equals 22.
Clause 18. The wireless communication device of clause 16, wherein the second low-density parity-check code is an NR low-density parity-check code based upon a base graph 2 in which N equals 10.
Clause 19. The wireless communication device of any of clauses 16-18, wherein the wireless communication device comprises a user equipment.
Clause 20. The wireless communication device of any of clauses 16-18, wherein the wireless communication device comprises a base station.
Clause 21. The wireless communication device of clause 16, further comprising:
   a shaping encoder configured to encode a plurality of input bits into a plurality of M amplitudes according to a probabilistic amplitude shaping, wherein M is a plural positive integer; and
   an amplitude-to-bit mapper configured to encode the plurality of M amplitudes into the plurality of N*Z information bits.
Clause 22. The wireless communication device of clause 21, further comprising:
   a constellation mapper configured to map the plurality of M amplitudes according to the second codeword into a plurality of n constellation symbols.
Clause 23. The wireless communication device of clause 22, wherein the constellation mapper is an amplitude-shift-key (ASK) constellation mapper.
Clause 24. A wireless communication device, comprising:
   a first low-density parity-check decoder configured to decode a first codeword according to first low-density parity-check code into a first output word in which an initial 2Z bits of the first output word are parity bits and in which a subsequent (N+2)*Z bits of the first output word includes N information bits, wherein Z is a lifting factor of the first low-density parity-check code and N is a plural positive integer; and
   a second low-density parity-check decoder configured to decode the first output word according a second low-density parity-check code into a second output word of the N information bits, wherein Z is also a lifting factor of the second low-density parity-check code.
Clause 25. The wireless communication device of clause 24, wherein the first low-density parity-check code is a new radio (NR) low-density parity-check code based upon a base graph 1 in which N equals 22.
Clause 26. The wireless communication device of clause 24, wherein the first low-density parity-check code is an NR low-density parity-check code based upon a base graph 2 in which N equals 10.
Clause 27. A computerized method of identifying parity bit columns for a low-density parity-check encoding, comprising:
   lifting a core low-density parity-check (LDPC) matrix according to a lifting factor Z to form a lifted LDPC matrix having a plurality of N+4 columns indexed from a first column to an (N+4)th column, wherein the first column and a second column in the lifted LDPC matrix are parity-bit columns and N is a positive plural integer identifying how many information-bit columns are in the lifted LDPC matrix, and wherein the lifting factor Z is selected from a class of lifting factors that are all proportional to a positive plural integer a; and
   determining a set of encodable patterns for the lifted LDPC matrix, wherein each encodable pattern is a set of four column indices identifying the parity-bit columns in the lifted LDPC matrix, and wherein the set of encodable patterns is the same for lifting factor in the class of lifting factors.
Clause 28. The computerized method of clause 27, further comprising:
   for each encodable pattern in the set of encodable patterns, forming a submatrix from the lifted LDPC matrix, wherein the submatrix comprises the parity-bit columns in the lifted LDPC matrix identified by the encodable pattern;
   converting each submatrix into an upper triangular submatrix having a fourth row of three zero elements and a final non-zero element;
   for each upper triangular submatrix's final non-zero element, factorizing an inverse of the final non-zero element to provide a corresponding set of factors; and
   selecting from the set of encodable patterns, an optimal encodable pattern which produces a smallest corresponding set of factors.
Clause 29. The method of clause 28, wherein the lifting factor Z is a largest lifting factor from the class of lifting factors, the method further comprising:
   cyclically shifting the corresponding set of factors for the optimal encodable pattern to determine a set of factors for an inverse of a final non-zero element corresponding to a smaller lifting factor from the class of lifting factors.
Clause 30. The method of any of clauses 27-29, wherein the core LDPC matrix is a core of base graph 1 or of base graph 2.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

1. A method for wireless communication by a wireless communication device, the method comprising:
generating a plurality (k) of information bits, wherein k is an integer greater than 1;
performing an encoding operation on the plurality of information bits, the encoding operation having a plurality of iterations and is constrained by a length (n) and a set of one or more target compositions of a plurality of sequences, the encoding operation including:
in a first iteration, calculating a first plurality of transition probabilities corresponding to a first plurality of prefix compositions;
in the first iteration, selecting a first symbol corresponding to a first prefix composition within the first plurality of prefix compositions based at least in part on the first plurality of transition probabilities;
in a second iteration, calculating a second plurality of transition probabilities corresponding to a second plurality of prefix compositions, wherein the second plurality of prefix compositions represents a remaining subset of the plurality of sequences associated with the first prefix composition; and
in the second iteration, selecting a second symbol corresponding to a second prefix composition within the second plurality of prefix compositions based at least in part on the second plurality of transition probabilities;
transmitting a wireless packet to at least one receiving device based on a sequence of length n, which is generated from the plurality of iterations, wherein n is equal to a total quantity of the plurality of iterations, further wherein the sequence comprises the first symbol and the second symbol.

2. The method of claim 1, wherein the set of one or more target compositions excludes at least one composition having one or more sequences of length (n).

3. The method of claim 1, further comprising:
performing n−2 further iterations subsequent to the second iteration, each of the n−2 further iterations generating one of the n symbols.

4. The method of claim 1, wherein a given target composition of the set of one or more target compositions includes m entries, wherein m is an integer greater than 1, wherein each one of the entries represents a quantity of occurrences of a respective symbol within a possible sequence within the plurality of sequences.

5. The method of claim 4, wherein a sum of the m entries is equal to n.

6. The method of claim 1, further comprising:
calculating a dyadic number based upon the plurality of information bits, and wherein selecting the first symbol includes determining that the dyadic number corresponds to a first transition probability of the first plurality of transition probabilities, the first transition probability corresponding to the first prefix composition.

7. The method of claim 6, further comprising:
calculating an updated input number from the dyadic number; and wherein selecting the second symbol includes determining that the updated input number corresponds to a second transition probability of the second plurality of transition probabilities, the second transition probability corresponding to the second prefix composition.

8. The method of claim 1, wherein a cardinality of the first plurality of prefix compositions is m, wherein m is an integer greater than 1 and represents a quantity of symbols within an alphabet of symbols.

9. The method of claim 1, wherein a given transition probability of the first plurality of transition probabilities is proportional to a first weighted sum of a first plurality of multinomial coefficients, wherein each multinomial coefficient of the first plurality of multinomial coefficients corresponds to a difference between a first respective target composition of the set of one or more target compositions and a given prefix composition of the first plurality of prefix compositions.

10. The method of claim 9, wherein a given transition probability of the second plurality of transition probabilities is proportional to a second weighted sum of a second plurality of multinomial coefficients, wherein each multinomial coefficient of the second plurality of multinomial coefficients corresponds to a difference between a second respective target composition of the set of one or more target compositions and a given prefix composition of the second plurality of prefix compositions.

11. The method of claim 1, further comprising:
receiving a subsequent wireless packet from a transmitting wireless communication device, the subsequent wireless packet including information having a received symbol sequence of n symbols and defined by an alphabet of symbols; and
decoding the subsequent wireless packet, wherein decoding comprises: performing a plurality (n) of decoding iterations, each decoding iteration including computing a plurality of transition probabilities in a decoding interval for a plurality of prefix compositions, and after n of the decoding iterations generating a binary expansion corresponding to a final decoding interval.

12. The method of claim 1, wherein the first iteration comprises:
partitioning a first interval into a first plurality of subintervals based at least in part on the first plurality of transition probabilities, wherein each subinterval of the first plurality of subintervals corresponds to a respective transition probability of the first plurality of transition probabilities, and a length of each subinterval of the first plurality of subintervals is proportional to a respective transition probability of the first plurality of transition probabilities; and
identifying a first subinterval of the first plurality of subintervals using a first number that is generated from the plurality of information bits, wherein the first subinterval corresponds to the first symbol.

13. The method of claim 1, wherein the encoding operation and the transmitting is performed by a wireless base station (BS) or a user equipment (UE).

14. A wireless communication device comprising:
at least one modem;
at least one processor coupled with the at least one modem; and
at least one memory coupled with the at least one processor and storing processor-readable code that, when executed by the at least one processor in conjunction with the at least one modem, is configured to:
perform an encoding operation on a plurality of information bits, the encoding operation having a plurality of iterations and is constrained by a length (n) and a set of one or more target compositions of a plurality of sequences, the encoding operation including:
in a first iteration, calculate a first plurality of transition probabilities corresponding to a first plurality of prefix compositions, wherein a given transition probability of the first plurality of transition probabilities is proportional to a first weighted sum of a first plurality of multinomial coefficients, wherein each multinomial coefficient of the first plurality of multinomial coefficients corresponds to a difference between a first respective target composition of the set of one or more target compositions and a given prefix composition of the first plurality of prefix compositions;
in the first iteration, select a first symbol corresponding to a first prefix composition within the first plurality of prefix compositions based at least in part on the first plurality of transition probabilities; and
perform further iterations of the plurality of iterations; and
transmit a wireless packet to at least one receiving device based on a sequence of length n, which is generated from the plurality of iterations, wherein n is equal to a total quantity of the plurality of iterations, further wherein the sequence comprises the first symbol.

15. The wireless communication device of claim 14, wherein a given target composition of the set of one or more target compositions includes m entries, wherein m is an integer greater than 1, wherein each one of the entries represents a quantity of occurrences of a respective symbol within a possible sequence within the plurality of sequences.

16. (canceled)

17. The wireless communication device of claim 14, wherein the at least one processor in conjunction with the at least one modem is further configured to:
calculate a dyadic number based upon the plurality of information bits, and wherein selecting the first symbol includes determining that the dyadic number corresponds to a first transition probability of the first plurality of transition probabilities, the first transition probability corresponding to the first prefix composition.

18. The wireless communication device of claim 17, wherein the at least one processor in conjunction with the at least one modem, is further configured to:
calculate an updated input number from the dyadic number; and
in a second iteration, determine that the updated input number corresponds to a second transition probability that corresponds to a second prefix composition.

19. The wireless communication device of claim 14, wherein a cardinality of the first plurality of prefix compositions is m, wherein m is an integer greater than 1 and represents a quantity of symbols within an alphabet of symbols.

20. The wireless communication device of claim 14, wherein the at least one processor in conjunction with the at least one modem is further configured to:
receive a subsequent wireless packet from a transmitting wireless communication device, the subsequent wireless packet including information having a received symbol sequence of n symbols and defined by an alphabet of symbols; and
decode the subsequent wireless packet, including: performing a plurality (n) of decoding iterations, each decoding iteration including computing a plurality of transition probabilities in a decoding interval for a plurality of prefix compositions, and after n of the decoding iterations generating a binary expansion corresponding to a final decoding interval.

21. (canceled)

22. (canceled)

23. (canceled)

24. (canceled)

25. (canceled)

26. A wireless communication device configured to encode a plurality of information bits, the wireless communication device comprising:
means for, in a first iteration, calculating a first plurality of transition probabilities corresponding to a first plurality of prefix compositions, wherein a given transition probability of the first plurality of transition probabilities is proportional to a first weighted sum of a first plurality of multinomial coefficients, wherein each multinomial coefficient of the first plurality of multinomial coefficients corresponds to a difference between a first respective target composition of a set of one or more target compositions and a given prefix composition of the first plurality of prefix compositions;
means for, in the first iteration, selecting a first symbol corresponding to a first prefix composition within the first plurality of prefix compositions based at least in part on the first plurality of transition probabilities;
means for performing further iterations of a plurality of iterations; and
means for transmitting a wireless packet to at least one receiving device based on an output sequence of length n, which is generated from the plurality of iterations, wherein n is equal to a total quantity of the plurality of iterations, further wherein the output sequence comprises the first symbol.

27. (canceled)

28. (canceled)

29. (canceled)

30. (canceled)
